(19) United States
(12) Patent Application Publication
(10) Pub. No.: US 2023/0345724 A1
(43) Pub. Date: Oct. 26, 2023

(54) SEMICONDUCTOR MEMORY DEVICE AND METHOD OF FABRICATING THE SAME

(71) Applicant: Fujian Jinhua Integrated Circuit Co., Ltd., Quanzhou City (CN)

(72) Inventors: Huixian LAI, Quanzhou City (CN); Li-Wei Feng, Quanzhou City (CN)

(73) Assignee: Fujian Jinhua Integrated Circuit Co., Ltd., Quanzhou City (CN)

(21) Appl. No.: 18/078,075

(22) Filed: Dec. 8, 2022

(30) Foreign Application Priority Data
Apr. 21, 2022 (CN) 202210427201.4
Apr. 21, 2022 (CN) 202220938337.7

(51) Int. Cl. H10B 43/27; H01L 21/762; H10B 41/10

(52) U.S. Cl. CPC H01L 27/11582; H01L 21/76224; H01L 27/11519

(57) ABSTRACT

The present disclosure provides a semiconductor memory structure and a method of fabricating the same includes a substrate; at least one first groove disposed on an upper surface of the substrate, with an edge corner of a top portion of the first groove being arc-shaped; a first dielectric layer disposed along an inner wall of the first groove; a second dielectric layer formed on a surface of the first dielectric layer, to fill up the first groove, wherein a top portion of the first dielectric layer is lower than a top portion of the second dielectric layer and an upper surface of the substrate, and a first recess is formed between the second dielectric layer and the substrate; and a metal filling layer disposed in the first recess, to fill in a partial space of the first recess.

### BACKGROUND OF THE INVENTION

### 1. Field of the Invention

The present disclosure relates generally to a semiconductor memory structure technology, and more particularly to a semiconductor memory device and a method of fabricating the same.

### 2. Description of the Prior Art

In the fabricating process of semiconductor memory, a groove is usually requested to be formed on a surface of a substrate, with the groove being filled by other material layers. While filling these material layers, an unexpected recess may be formed on the surface of the substrate, as shown in FIG. 2. As shown in FIG. 1 and FIG. 2, a substrate 101 includes a plurality of active areas and a shallow trench isolation surrounding the active areas, and a first material layer 103, a second material layer 104 and a third material layer 105 are sequentially filled in a groove 100 where the shallow trench isolation structure is disposed therein, with the top portion of the first material layer 103 being higher than the surface of the substrate 101, and being lower than the top portion of the second material layer 104, so that, recesses 102 are formed between the second material layer 104 and the substrate 101. Also, a plurality of buried word lines 110 are formed in the substrate, extended along a y-direction, to intersect with the active areas of the substrate 101 and the shallow trench isolation at the same time, wherein each of the buried word lines 110 further includes a gate dielectric layer, a gate electrode layer, and a hard mask layer stacked sequentially. The recess 102 is difficulty to be filled and leveled during the subsequent fabricating process of the semiconductor memory, and also, the collapse caused by the accumulation of the material layers in the subsequent fabricating processes may be easily occurred, thereby affecting the flatness of the semiconductor memory and the yield of the semiconductor memory.

### SUMMARY OF THE INVENTION

According to these, the present disclosure provides a semiconductor memory device and a method of fabricating the same, to reduce the recesses which are occurred during filling the recesses with plural material layers, so as to increase the yield of the semiconductor memory device.

The present disclosure provides a semiconductor memory structure including a substrate; at least one first groove disposed on an upper surface of the substrate, with an edge corner of a top portion of the first groove being arc-shaped; a first dielectric layer disposed along an inner wall of the first groove; a second dielectric layer disposed on a surface of the first dielectric layer, to fill up the first groove, wherein a top portion of the first dielectric layer is lower than a top portion of the second dielectric layer and an upper surface of the substrate, and a first recess is formed between the second dielectric layer and the substrate; and a metal filling layer disposed in the first recess, to fill in a partial space of the first recess.

Optionally, a third dielectric layer is disposed on a top portion of the metal filling layer, within the first recess, to fill up the first recess.

Optionally, the second dielectric layer includes a first sublayer and a second sublayer, the first sublayer is disposed on the surface of the first dielectric layer, and the second sublayer is disposed on a surface of the first sublayer and filled up the first groove.

Optionally, the first dielectric layer includes an oxide dielectric layer and/or the second dielectric layer includes a nitride dielectric layer.

Optionally, the first sublayer includes a nitride dielectric layer, and the second sublayer includes an oxide dielectric layer.

Optionally, a fourth dielectric layer covers an inner wall of the first recess, and the fourth dielectric layer is filled in a partial space of the first recess.

Optionally, an insulating layer is disposed on the top portion of the second dielectric layer, the top portion of a metal filling layer and the upper surface of the substrate.

Optionally, a gate stacked structure, is disposed on a top portion of the substrate, and/or; a loading stacked structure is disposed on the top portion of the second dielectric layer.

Optionally, the gate stacked structure at least sequentially includes a first polysilicon layer, a first conductive layer and a first mask layer from bottom to top in a direction being perpendicular to the upper surface of the substrate and/or, the loading stacked structure sequentially includes a second polysilicon layer, a second conductive layer and a second mask layer from bottom to top in the direction being perpendicular to the upper surface of the substrate.

Optionally, a fabricating material of the metal filling layer is the same as a fabricating material of the first conductive layer or the second conductive layer.

The present disclosure provides a method of fabricating a semiconductor memory structure including following steps: providing a substrate, with a first groove being formed at an upper surface of the substrate; sequentially forming a first dielectric material layer, a second dielectric material layer along an inner wall of the first groove; partially removing the first dielectric material layer and the second dielectric material layer, with an edge corner of a top portion of the first groove being arc-shaped to correspondingly form a first dielectric layer and a second dielectric layer respectively, and with a top portion of the first dielectric layer being lower than a top portion of the second dielectric layer and the upper surface of the substrate to form a first recess between the second dielectric layer and the substrate; and forming a metal filling layer in the first recess to partially fill in the first recess.

Optionally, after forming the metal filling layer in the first recess further including following steps: a third dielectric layer is formed on a top portion of the metal filling layer, and the third dielectric layer is filled up the first recess.

Optionally, partially removing the first dielectric material layer and the second dielectric material layer further includes following steps: using at least one of a dry etching process and a wet etching process, to partially removing the first dielectric material layer and the second dielectric material layer, with an etching rate of an etching selecting gas or an etching liquid related to the first dielectric material layer being greater than that of the second dielectric material layer.

Optionally, the second dielectric layer includes a first sublayer and a second sublayer, while forming the second dielectric layer includes following steps: forming the first sublayer on the surface of a first dielectric layer; and forming the second sublayer on a surface of the first sublayer, and the second sublayer filled up the first groove.

Optionally, before forming the metal filling layer in the first recess further includes following steps: forming a fourth dielectric layer on an inner wall of the first recess.

Optionally, forming the metal filling layer in the first recess includes: forming a metal layer in the first recess, on the top portion of the second dielectric and on the upper surface of the substrate, the metal layer at least filled up the first recess; and performing an etching back process on the metal layer, to remain the metal layer filled in the first recess to form the metal filling layer.

Optionally, forming the third dielectric layer on the top portion of the metal filling layer includes: forming a dielectric material layer on the top portion of the metal filling layer, the top portion of the second dielectric layer and the upper surface of the substrate, the dielectric material layer at least filled up the first recess; and performing an etching back process on the dielectric material layer, to remain the dielectric material layer filled in the first recess to form the third dielectric layer.

According to the semiconductor memory structure and the method of fabricating the same of the present disclosure, the metal filling layer is used to fill in a partially space of the first recess. Since the metal filling layer has a relative higher strength and a certain ductility, after filling the first recess with the metal filling layer, the probability of the collapse of the first recess is obviously reduced in the subsequent fabricating process of the semiconductor memory structure. Then, the possibility of the collapse of the filled first recess may be reduced, as the unexpected recess on the upper surface of the substrate may be effectively eliminated, thereby obtaining a better recess filling effect and effectively improving the yield of the semiconductor memory structure.

In addition, since the first recess is filled with a metal material, the metal filling layer may be utilized to position the boundary of the first groove in the subsequent fabricating processes of the semiconductor memory structure, due to the opacity and good light reflection performance of the metal filling layer. Then, the center position of the first groove may be determined thereby to achieve a better film alignment effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 2 illustrate schematic diagrams of a top view and a cross-sectional view of a conventional semiconductor memory structure.

FIG. 3 illustrates a schematic flowchart of the fabricating method of the semiconductor memory structure according to one embodiment of the present disclosure.

FIG. 4 to FIG. 17 illustrate schematic diagrams corresponding to each step of the fabricating method of the semiconductor memory device according to the present disclosure.

FIG. 18 illustrates a schematic diagram of the semiconductor memory device according to one embodiment of the present disclosure.

FIG. 19 illustrates a schematic diagram of the semiconductor memory device according to one embodiment of the present disclosure.

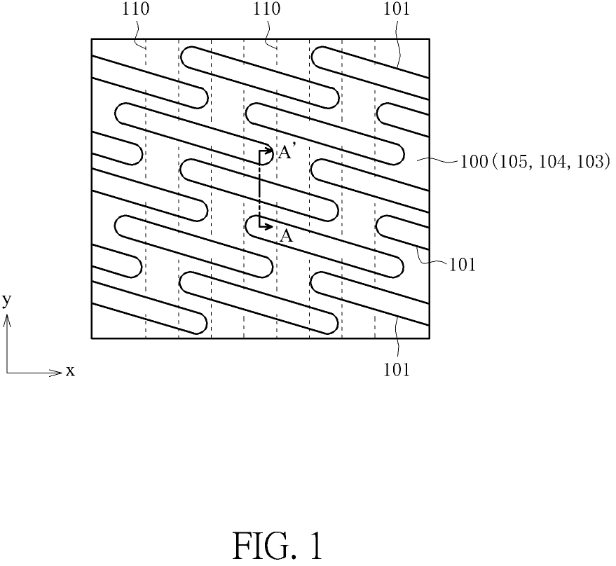

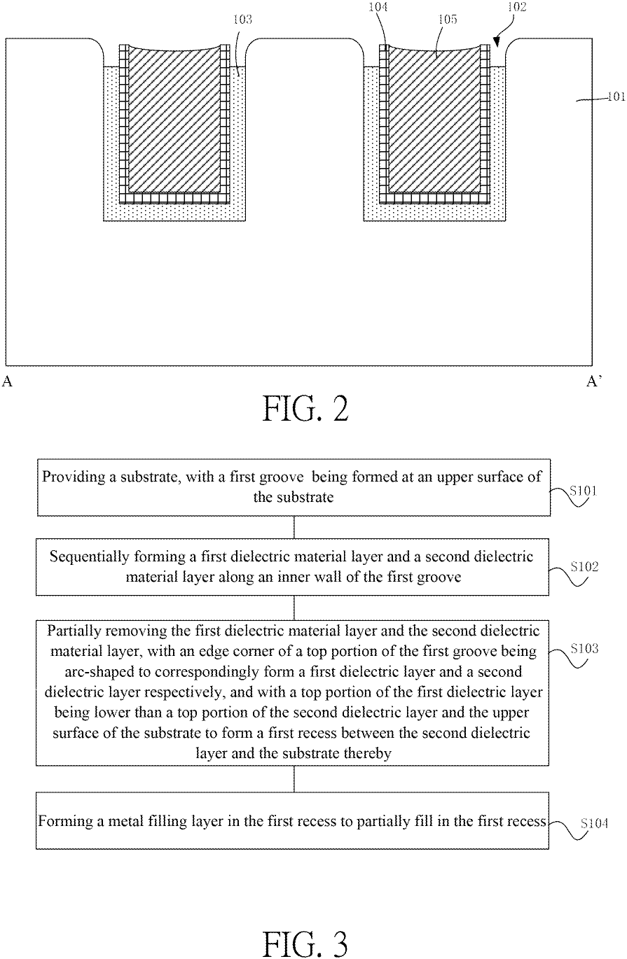

### DETAILED DESCRIPTION

To provide a better understanding of the presented disclosure, preferred embodiments will be described in detail. The preferred embodiments of the present disclosure are illustrated in the accompanying drawings with numbered elements.

In the first aspect, the present disclosure provides a method of fabricating a semiconductor memory structure.

Please refer to FIG. 3, which illustrates a schematic flowchart of the fabricating method of the semiconductor memory structure according to one embodiment.

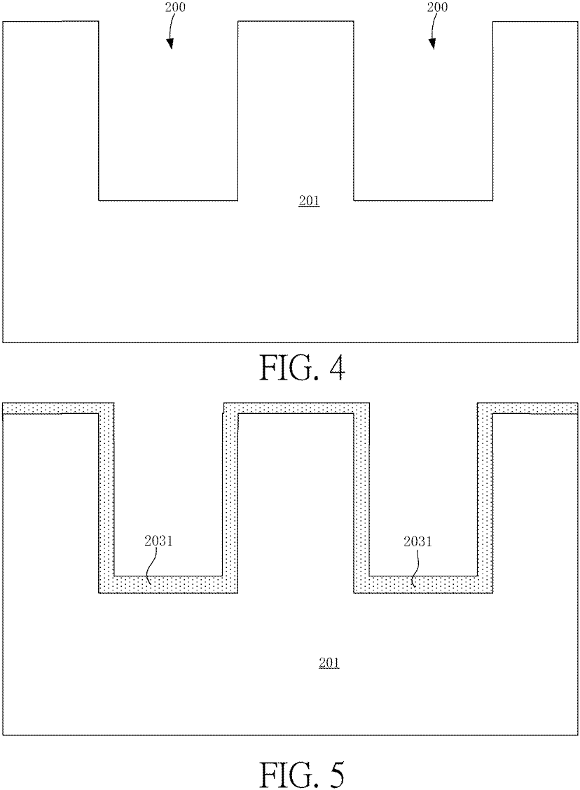

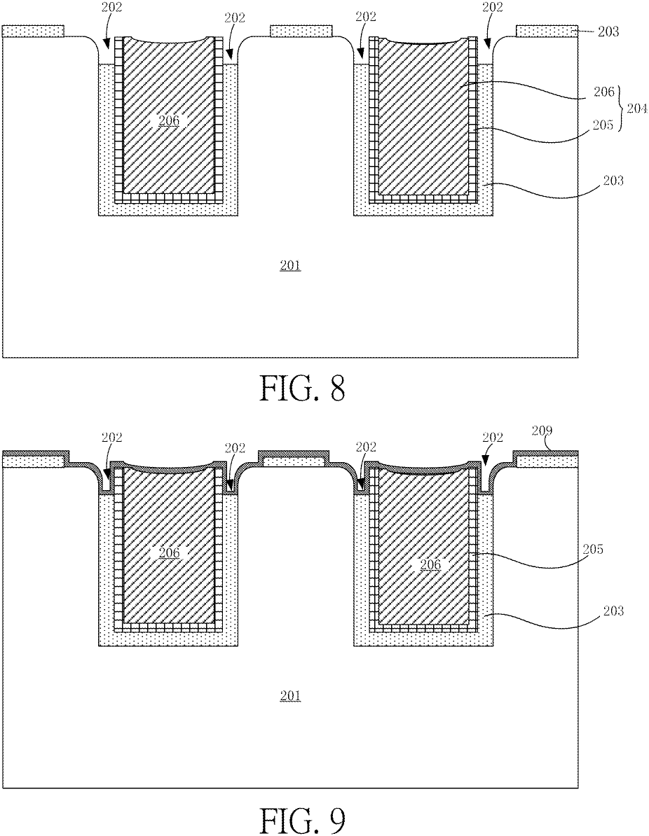

In the present embodiment, the fabricating method of the semiconductor memory structure includes following steps: a step S101: providing a substrate 201, with a first groove 200 being formed at an upper surface of the substrate 201 (as shown in FIG. 4); a step S102: sequentially forming a first dielectric material layer 2031 (as shown in FIG. 5) and a second dielectric material layer along an inner wall of the first groove 200; a step S103: partially removing the first dielectric material layer 2031 and the second dielectric material layer, with an edge corner of a top portion of the first groove 200 being arc-shaped to correspondingly form a first dielectric layer 203 and a second dielectric layer 204 respectively, and with a top portion of the first dielectric layer 203 being lower than a top portion of the second dielectric layer 204 and the upper surface of the substrate 201 to form a first recess 202 (as shown in FIG. 8) between the second dielectric layer 204 and the substrate 201 thereby; and a step S104: forming a metal filling layer 207 in the first recess 202 to partially fill in the first recess 202 (as shown in FIG. 11).

According to the method of fabricating the semiconductor memory structure of the present disclosure, the metal filling layer 207 is used to fill in a partially space of the first recess 202. Since the metal filling layer 207 has a relative higher strength and a certain ductility, after filling the first recess 202 with the metal filling layer 207, the probability of the collapse of the first recess 202 is obviously reduced in the subsequent fabricating process of the semiconductor memory structure. Then, the possibility of the collapse of the filled first recess 202 may be reduced, as the unexpected recess on the upper surface of the substrate 201 may be effectively eliminated, thereby obtaining a better recess filling effect and effectively improving the yield of the semiconductor memory structure.

In addition, since the first recess 202 is filled with a metal material, the metal filling layer may be utilized to position the boundary of the first groove 200 in the subsequent fabricating processes of the semiconductor memory structure, due to the opacity and the good light reflection performance of the metal filling layer. Then, the center position of the first groove 200 may be determined thereby to achieve a better film alignment effect.

In some embodiments, after forming the metal filling layer 207 in the first recess 202, the fabricating method further includes following steps: a third dielectric layer 208 is formed on a top portion of the metal filling layer 207, and the third dielectric layer 208 is filled up the first recess 202 (as shown in FIG. 13).

In these embodiments, the rest portion of the first recess 202 is filled with the third dielectric layer 208, so as to effectively isolate the electrical connection between the metal filling layer 207 and other conductive structures, thus achieving a certain insulating effect, and to prevent the metal filling layer 207 from shorting connection with other conductive structures, without leading to the damage of the semiconductor memory structure.

In some embodiment, the step of partially removing the first dielectric material layer 2031 and the second dielectric material layer further includes following steps: using at least one of a dry etching process and a wet etching process, to partially remove the first dielectric material layer 2031 and the second dielectric material layer, with an etching rate of an etching selecting gas or an etching liquid related to the first dielectric material layer 2031 being greater than that of the second dielectric layer 204. Then, after the etching process, a height of the top portion of the first dielectric layer 203 is lower than a height of the top portion of the second dielectric layer 204.

In some embodiment, while partially removing the first dielectric material layer 2031 and the second dielectric material layer further includes following steps: forming a third mask layer 218 on an upper surface of the first dielectric layer 203, patterning the third mask layer 218 to exposed the first dielectric material layer 2031 and the second dielectric material layer filled in the first groove 200, and the first dielectric material layer 2031 disposed at the edge of the first groove 200, so that, the etching gas or the etching liquid may selectively etch the first dielectric material layer 2031 at the inner side and the edge of the first groove 200 to obtain the required profile, as shown in FIG. 7.

In some further embodiments, the etching rate of the etching gas or the etching liquid related to the fist dielectric material layer 2031 is greater than that of the substrate 201, so that, after the etching process, a height of the top portion of the first dielectric layer 203 is lower than a height of the upper surface of the substrate 201, as shown in FIG. 8.

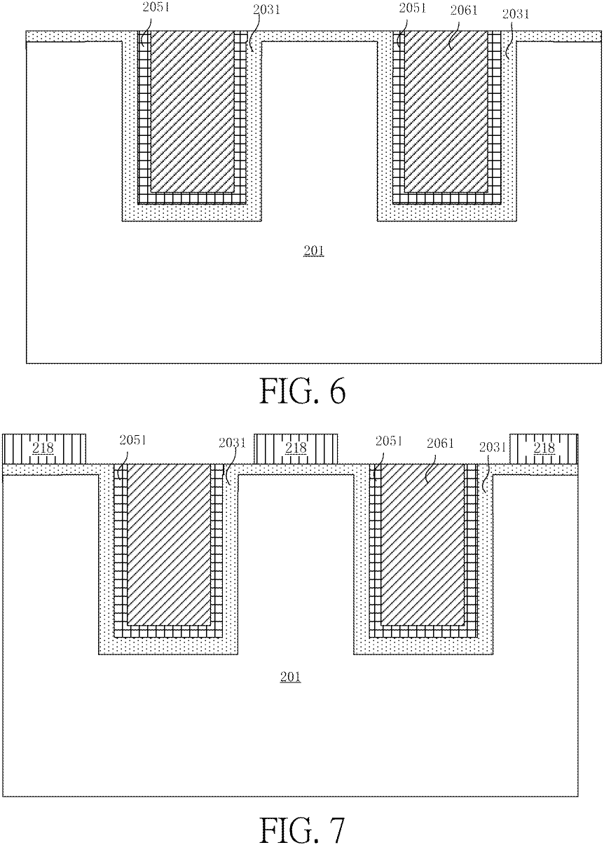

In some embodiments, the second dielectric layer 204 includes a first sublayer 205 and a second sublayer 206. While forming the second dielectric layer 204, the fabricating method includes following steps: forming a first sub-material layer 2051 on the surface of a first dielectric layer 203; and forming a second sub-material layer 2061 on a surface of the first sub-material layer 2051, and the second sub-material layer 2061 filled up the first groove 200, as shown in FIG. 6.

As shown in the embodiment of FIG. 8, the first dielectric layer 203 includes an oxide dielectric layer, the first sublayer 205 includes a nitride dielectric layer, and the second sublayer 206 includes an oxide dielectric layer. At this time, after performing the etching process, the top portion of the first sublayer 205 is higher than the top portion of the first dielectric layer 203, and is also higher than the top portion of the second sublayer 206. The filling within the first groove 200 is recessed in the center portion.

As shown in the embodiment of the FIG. 19, the second dielectric layer 204 only includes a single dielectric layer, instead of a plurality of individual sublayers. In some embodiments, the first dielectric layer 203 includes an oxide dielectric layer, and the second dielectric layer 204 includes a nitride dielectric layer.

Before forming the metal filling layer 207 in the first recess 202, the fabricating method further includes following steps: forming a fourth dielectric layer 209 on an inner surface of the first recess 202, as shown in FIG. 9. It is noted that the fourth dielectric layer 209 is namely a gate dielectric layer (not shown in the drawings) of a buried word line (not shown in the drawings) formed in the subsequent process.

The fourth dielectric layer 209 is partially disposed between the metal filling layer 207 and the substrate 201, to isolate the electrically connection between the metal filling layer 207 and the substrate 201, and to prevent from the short connection between the metal filling layer 207 and the substrate 201, thus avoiding the electrical damage of the semiconductor memory structure caused by the metal filling layer 207.

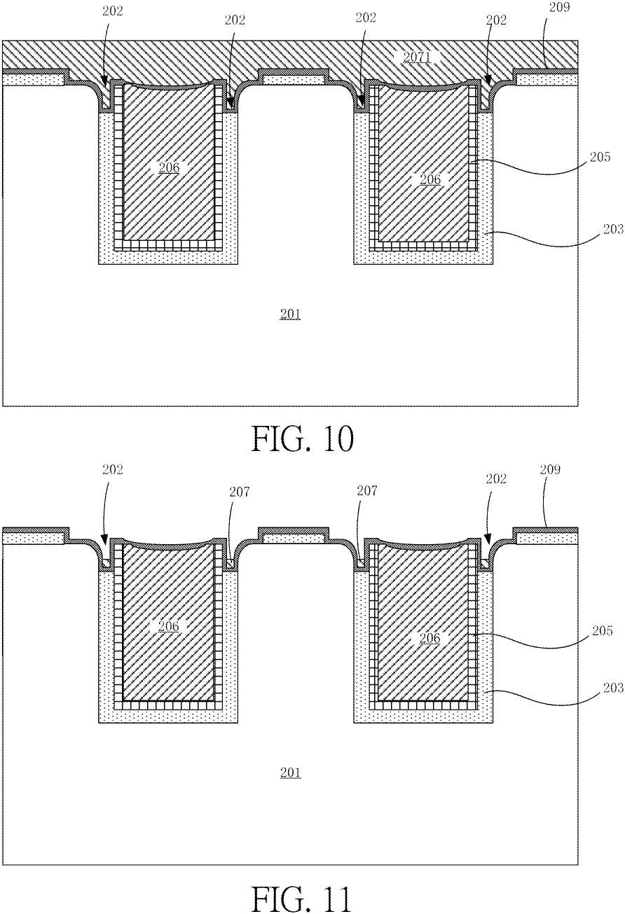

Forming the metal filling layer 207 in the first recess 202 further includes: forming a metal layer 2071 in the first recess 202, on the top portion of the second dielectric layer 204 and on the upper surface of the substrate 201, the metal layer 2071 at least filled up the first recess 202, as shown in FIG. 10; and performing an etching back process on the metal layer 2071, to remain the metal layer 2071 filled in the first recess 202 to form the metal filling layer 207, as shown in FIG. 11. It is noted that the metal layer 2071 is namely a gate electrode material layer (not shown in the drawings) for forming a gate electrode layer (not shown in the drawings) of the buried word line formed in the subsequent process, and the gate electrode layer of the buried word line is formed after etching back the metal layer 2071.

In some embodiments, at least one of a physical deposition process and a chemical deposition process is used to form the metal layer 2071 in the first recess 202. Also, the metal layer 2071 is etched back by performing at least one of a dry etching process and a wet etching process, and the etching rates of the etching back process related to the fourth dielectric layer 209 and the metal layer 2071 are related higher.

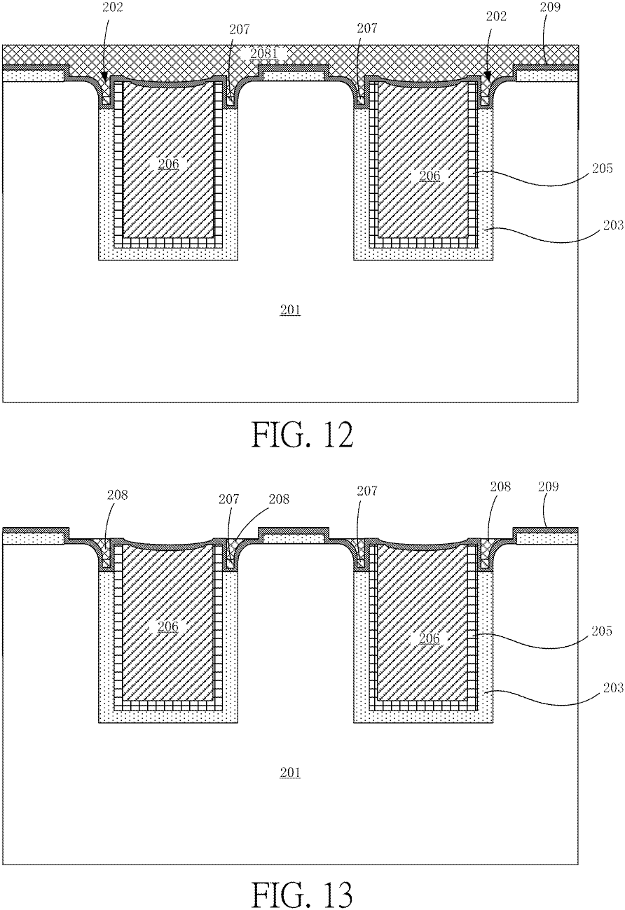

Forming the third dielectric layer 208 on the upper surface of the metal filling layer 207 includes: forming a dielectric material layer 2081 on the top portion of the metal filling layer 207, the top portion of the second dielectric layer 204, and the upper surface of the substrate 201, with the dielectric material layer 2081 at least filling up the first recess 202, as shown in FIG. 12, and etching back the dielectric material layer 2081, to remain the dielectric material layer 2081 filled in the first recess 202 to serve as the third dielectric layer 208, as shown in FIG. 13. It is noted that the dielectric material layer 2081 is namely a hard mask material layer (not shown in the drawings) for forming a hard mask layer (not shown in the drawings) of the buried word line formed in the subsequent process, and the hard mask layer of the buried word line is formed after etching back the dielectric material layer 2081. Accordingly, the buried word line including the gate dielectric layer, the gate electrode layer and the hard mask layer stacked sequentially is formed within the substrate 201, while the third dielectric layer 208 is formed, with the hard mask layer being formed with the third dielectric layer 208, with the gate electrode layer being formed with the metal filling layer 207, and with the gate dielectric layer being formed with the fourth dielectric layer 209.

In some embodiments, the dielectric material layer 2081 is formed through at least one of a physical deposition process, a chemical deposition process, and an atomic layer deposition process. The dielectric material layer 2081 includes a silicon nitride layer. The third dielectric layer 208 of the present embodiments is used to isolate the electrical connection between the metal filling layer 207 and other conductive structures, thus achieving a certain insulation effect, and to prevent the metal filling layer 207 from shorting connection with other conductive structures, without leading to the damage of the semiconductor memory structure.

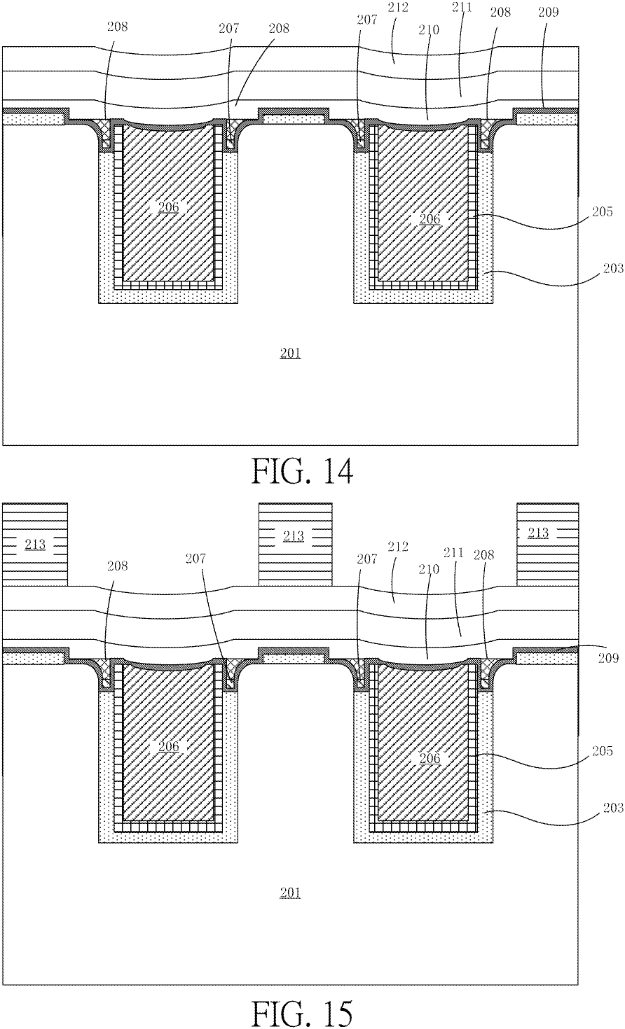

In some embodiments, the fabricating method further includes forming a gate stacked structure 300 on the upper surface of the substrate 201. As shown in FIG. 14, a first polysilicon layer 210, a first conductive layer 211, and a first mask layer 212 of the gate stacked structure 300 are sequentially formed on the surface of the substrate 201. After that, as shown in FIG. 15, a fourth mask layer 213 is formed on the upper surface of the first mask layer 212, and the fourth mask layer 213 is patterned to exposed the first mask layer 212 disposed on the first groove 200.

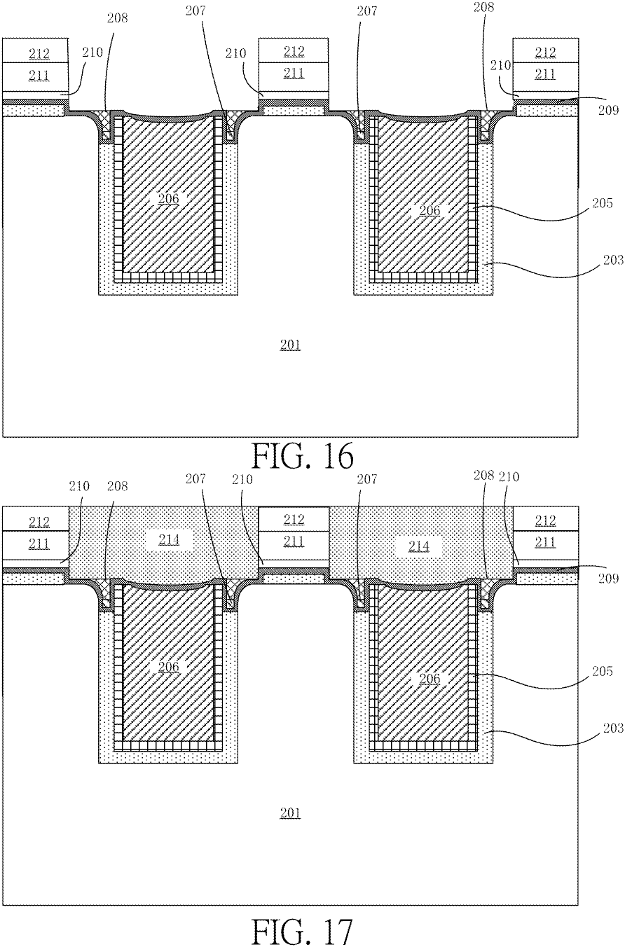

After that, as shown in FIG. 16, the first mask layer 212, the first conductive layer 211, and the first polysilicon layer 210 are etched downwardly along a direction being perpendicular to the first mask layer 212, to expose the fourth dielectric layer 209, and the third dielectric layer 208 filled in the first recess 202. As shown in FIG. 17, an insulating layer 214 is formed on the upper surface of the exposed fourth dielectric layer 209, and then, the fabrication of the gate stacked structure 300 is accomplished. The insulating layer 214 includes a silicon oxide layer.

In some embodiments, the fabricating method further includes forming a loading stacked structure 301 on the top portion of the second dielectric layer 204, for providing a better loading effect to the gate stacked structure 300. While fabricating the loading stacked structure 301, the metal filling layer 207 filled in the first recess 202 may further be used for positioning.

Precisely, the first mask layer 212 and the second mask layer 2121 are form through partially removing the same mask material layer, the first conductive layer 211 and the second conductive layer 2111 are formed through partially removing the same conductive material layer, and the first polysilicon layer 210 and the second polysilicon layer 2101 are formed through partially removing the same polysilicon material layer, so that, the loading stacked structure 301 and the gate stacked structure 300 may be simultaneously formed by only forming patterned mask layers on the topmost mask material layer and exposing an area being corresponding to the marked position by the metal filling layer 207.

A first patterned photomask is required to expose an area being corresponding to the metal filling layer 207.

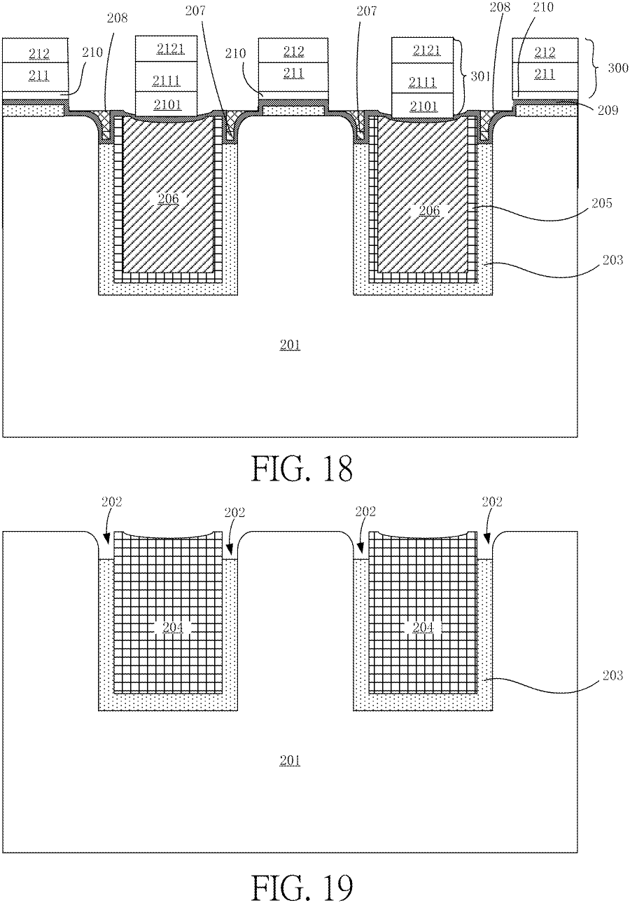

In some embodiments, the loading stacked structure 301 includes a second polysilicon layer 2101, a second conductive layer 2111, and a second mask layer 2121 sequentially stacked form bottom to top in a direction being perpendicular to the upper surface of the substrate 201, as shown in FIG. 18.

In some embodiments, at least one gate stacked structure (not shown in the drawings) further covering the third dielectric layer 208 filled in the first recess 202 may also be formed on the substrate 201, overlapping the metal filling layer 207 underneath, so that, the at least one gate stacked structure may therefore cross over the metal filling layer 207 within the first recess 202, with the third dielectric layer 208 being isolated between the metal filling layer 207 and the first polysilicon layer 210 of the at the least one gate stacked structure. The at least one gate stacked structure is preferably formed in a certain area of the semiconductor memory structure, such as a periphery region of the semiconductor memory structure, to obtain a relative greater width in comparison with other gate stacked structures 300.

In the second aspect, the present disclosure provides a semiconductor memory structure.

Please refer to FIG. 13, which illustrates a schematic diagram of the semiconductor memory structure according to one embodiment of the present disclosure.

In the present embodiment, the semiconductor memory structure includes: a substrate 201; at least one first groove 200 disposed on an upper surface of the substrate 201, with an edge corner on a top portion of the first groove 200 being arc-shaped; a first dielectric layer 203 disposed along an inner wall of the first groove 200; a second dielectric layer 204 disposed on a surface of the first dielectric layer 203, to fill up the first groove 200, wherein a top portion of the first dielectric layer 203 is lower than a top portion of the second dielectric layer 204 and an upper surface of the substrate 201, and a first recess 202 is formed between the second dielectric layer 204 and the substrate 201; and a metal filling layer 207 disposed in the first recess 202, to fill in a partial space of the first recess 202.

According to the semiconductor memory structure of the present disclosure, the metal filling layer 207 is used to fill in a partially space of the first recess 202. Since the metal filling layer 207 has a relative higher strength and a certain ductility, after filling the first recess 202 with the metal filling layer 207, the probability of the collapse of the first recess 202 is obviously reduced in the subsequent fabricating process of the semiconductor memory structure. Then, the possibility of the collapse of the filled first recess 201 may be reduced, as the unexpected recess on the upper surface of the substrate 201 may be effectively eliminated, thereby obtaining a better recess filling effect and effectively improving the yield of the semiconductor memory structure.

In addition, since the first recess 202 is filled with a metal material, the metal filling layer 207 may be utilized to position the boundary of the first groove 200 in the subsequent fabricating processes of the semiconductor memory structure, due to the opacity and good light reflection performance of the metal filling layer 207. Then, the center position of the first groove 200 may be determined thereby to achieve a better film alignment effect.

In some other embodiments, the semiconductor memory structure further includes: a third dielectric layer 208 disposed on a top portion of the metal filling layer 207, within the first recess 202, to fill up the first recess 202.

The rest portion of the first recess 202 is filled with the third dielectric layer 208, so as to effectively isolate the electrical connection between the metal filling layer 207 and other conductive structures, thus achieving a certain insulating effect, and to prevent the metal filling layer 207 from shorting connection with other conductive structures, without leading to the damage of the semiconductor memory structure.

In these embodiments, the first recess 202 is formed because the edge corner of the top portion of the first groove 200 requires being arc-shaped, without sharp corners to achieve further smoother, so as to reduce the probability of discharging at the edge corners of the first groove 200.

In some embodiments, the method of making the edge corner of the top portion of the first groove 200 being arc-shaped includes: firstly forming the first groove 200, sequentially forming the first dielectric layer 203 and the second dielectric layer 204 along an inner wall of the first groove 200, with the first dielectric layer 203 covering on the upper surface of the substrate 201. Then, a photomask is formed on the upper surface of the first dielectric layer 203, and the photomask is patterned to expose the filling within the first groove 200, and a first portion of the first dielectric layer 203 disposed on the upper surface of the substrate 201, wherein the first portion is disposed along the edge corner of the first groove 200. After that, the filling within the first groove 200 and the first portion of the first dielectric layer 203 disposed on the upper surface of the substrate 201 are partially removed along the exposed area of the patterned photomask, so that, the arc-shaped treatment of the edge corner of the first groove 200 may be accomplished.

In these embodiments, the first dielectric layer 203 and the second dielectric layer 204 have different materials.

In the embodiment as shown in FIG. 19, the second dielectric layer 204 only includes a single-layered dielectric layer instead of a plurality of individual sublayers. In some embodiments, the first dielectric layer 203 includes an oxide dielectric layer, and the second dielectric layer 204 includes a nitride dielectric layer.

While performing the arc-shaped treatment, since the materials of the first dielectric layer 203 and the second dielectric layer 204 are different, the etching rate of the etching gas or the etching liquid related to the first dielectric layer 203 and the second dielectric layer 204 are different accordingly. In the embodiment as shown in FIG. 4, the etching rate of the selected etching gas or the etching liquid related to the first dielectric layer 203 is greater than that of the second dielectric layer 204, and the etching rate of the etching gas or the etching liquid related to the first dielectric layer 203 is greater than that of the substrate 201. After the etching, the top portion of the first dielectric layer 203 is lower than the top portion of the second dielectric layer, and the upper surface of the substrate 201.

As shown in FIG. 13, the second dielectric layer 204 includes a first sublayer 205 and a second sublayer 206, the first sublayer 205 is formed on the surface of the first dielectric layer 203, and the second sublayer 206 is formed on the surface of the first sublayer 205 and filled up the first groove 200.

In some embodiments, the first dielectric layer 203 includes an oxide dielectric layer, the first sublayer 205 includes a nitride dielectric layer, and the second dielectric layer 206 includes an oxide dielectric layer. At this time, after performing the etching process, the top portion of the first sublayer 205 is higher than the top portion of the first dielectric layer 203, and is also higher than the top portion of the second sublayer 206, such that, the filling within the first groove 200 is recessed in the center portion.

In some other embodiments, the practical material of the second dielectric layer 204 may be selected based on requirements.

The semiconductor memory structure further includes a fourth dielectric layer 209, the forth dielectric layer 209 covers the inner wall of the first recess 202, and the upper surface of the substrate 201, and the fourth dielectric layer 209 is filled in a partial space of the first recess 202. The fourth dielectric layer 209 is partially disposed between the metal filling layer 207 and the substrate 201, which enables to cut off the electrical connection between the metal filling layer 207 and the substrate 201, preventing from the shorting connection of the metal filling layer 207 and the substrate 201, and further preventing from the electrical damages of the semiconductor memory structure caused by the metal filling layer 207.

In some other embodiments, the semiconductor memory structure further includes: an insulating layer 214 formed on the top portion of the second dielectric layer 204, the top portion of the metal filling layer 207, and the upper surface of the substrate 201. Precisely, the insulating layer 214 is disposed on a partial area of the upper surface of the substrate 201, and is closed to the first groove 200.

In some other embodiments, a third dielectric layer 208 is formed on the metal filling layer 207, with the insulating layer 214 also disposed on the top portion of the third dielectric layer 208.

In some embodiments, the semiconductor memory structure further includes: a gate stacked structure 300 formed on the top portion of the substrate 201, and/or; a loading stacked structure 301 formed on the top portion of the second dielectric layer 204.

In some embodiments, the gate stacked structure 300 at least includes a first polysilicon layer 210, a first conductive layer 211 and a first mask layer 212 stacked sequentially from bottom to top in a direction being perpendicular to the upper surface of the substrate 201 for forming a connection lines.

In some other embodiments, the loading stacked structure 301 includes a second polysilicon layer 2101, a second conductive layer 2111 and a second mask layer 2121 stacked sequentially from bottom to top in the direction being perpendicular to the upper surface of the substrate 201, as shown in FIG. 18.

In some embodiments, the first conductive layer 211 and the second conductive layer 2111 include at least one of the conductive materials like cooper, tungsten, and titanium nitride. As shown in the embodiment as shown in FIG. 13, the first conductive layer 211 and/or the second conductive layer 2111 only include the first conductive layer 211 only including a single conductive material, for example being one of a tungsten layer, a titanium nitride layer, or a copper layer. In some other embodiments, the first conductive layer 211 and/or the second conductive layer 211 may further include two conductive material layers which are adjacent to each other. In some embodiments, the conductive material layer which is closed to the substrate 201 may be a tungsten layer or a titanium nitride layer, and the conductive material layer which is away from the substrate 201 may be a titanium nitride layer or a tungsten layer.

In some embodiments, the top portion of the first polysilicon layer 210 is coplanar with the top portion of the second polysilicon layer 2101, the top portion of the first conductive layer 211 is coplanar with the top portion of the second conductive layer 2111, and the top portion of the first mask layer 212 is coplanar with the top portion of the second mask layer 2121.

In some embodiments, at least one gate stacked structure (not shown in the drawings) further covers the third dielectric layer 208 and the metal filling layer 207 filled in the first recess 202 underneath, so that, the at least one gate stacked structure may therefore cross over the metal filling layer 207 within the first recess 202, with the third dielectric layer 208 being isolated between the metal filling layer 207 and the first polysilicon layer 210 of the at the least one gate stacked structure. The at least one gate stacked structure is preferably disposed in a certain area of the semiconductor memory structure, such as a periphery region of the semiconductor memory structure, to obtain a relative greater width in comparison with the gate stacked structures 300 or the loading stacked structure 301.

In some embodiments, the fabricating material of the metal filling layer 207 is the same as the fabricating material of the first conductive layer 211, so that, the same set of metal deposition equipment and metal target may be used to form the metal filling layer 207 and the first conductive layer 211, which reduces the fabricating difficulty.

In some embodiments, the metal filling layer 207 may be formed by using the conductive material like titanium, tungsten, or titanium nitride. Actually, the precise fabricating materials of the first conductive layer 211 and the metal filling layer 207 may also be selected based on requirements.

The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor memory structure, comprising:
a substrate;
at least one first groove disposed on an upper surface of the substrate, with an edge corner of a top portion of the first groove being arc-shaped;
a first dielectric layer, disposed along an inner wall of the first groove;
a second dielectric layer, disposed on a surface of the first dielectric layer, to fill up the first groove, wherein a top portion of the first dielectric layer is lower than a top portion of the second dielectric layer and an upper surface of the substrate, and a first recess is disposed between the second dielectric layer and the substrate; and
a metal filling layer, disposed in the first recess, to fill in a partial space of the first recess.

2. The semiconductor memory structure according to claim 1, further comprising:
a third dielectric layer, disposed on a top portion of the metal filling layer, within the first recess, to fill up the first recess.

3. The semiconductor memory structure according to claim 1, wherein the second dielectric layer comprises a first sublayer and a second sublayer, the first sublayer is disposed on the surface of the first dielectric layer, and the second sublayer is disposed on a surface of the first sublayer and filled up the first groove.

4. The semiconductor memory structure according to claim 1, wherein the first dielectric layer comprises an oxide dielectric layer and/or the second dielectric layer comprises a nitride dielectric layer.

5. The semiconductor memory structure according to claim 3, wherein the first sublayer comprises a nitride dielectric layer, and the second sublayer comprises an oxide dielectric layer.

6. The semiconductor memory structure according to claim 1, further comprising:
a fourth dielectric layer, covering an inner wall of the first recess, and the fourth dielectric layer filled in a partial space of the first recess.

7. The semiconductor memory structure according to claim 1, further comprising:
an insulating layer, disposed on the top portion of the second dielectric layer, the top portion of a metal filling layer and the upper surface of the substrate.

8. The semiconductor memory structure according to claim 1, further comprising:
a gate stacked structure, disposed on a top portion of the substrate, and/or;
a loading stacked structure, disposed on the top portion of the second dielectric layer.

9. The semiconductor memory structure according to claim 8, wherein the gate stacked structure at least comprises a first polysilicon layer, a first conductive layer and a first mask layer stacked sequentially from bottom to top in a direction being perpendicular to the upper surface of the substrate and/or, the loading stacked structure comprises a second polysilicon layer, a second conductive layer and a second mask layer stacked sequentially from bottom to top in the direction being perpendicular to the upper surface of the substrate.

10. The semiconductor memory structure according to claim 9, wherein a fabricating material of the metal filling layer is the same as a fabricating material of the first conductive layer or the second conductive layer.

11. The semiconductor memory structure according to claim 8, wherein the gate stacked structure crosses over the metal filling layer.

12. A method of fabricating a semiconductor memory structure, comprising following steps:
providing a substrate, with a first groove being formed at an upper surface of the substrate;
sequentially forming a first dielectric material layer, a second dielectric material layer along an inner wall of the first groove;
partially removing the first dielectric material layer and the second dielectric material layer, with an edge corner of a top portion of the first groove being arc-shaped to correspondingly form a first dielectric layer and a second dielectric layer respectively, and with a top portion of the first dielectric layer being lower than a top portion of the second dielectric layer and the upper surface of the substrate to form a first recess between the second dielectric layer and the substrate; and
forming a metal filling layer in the first recess to partially fill in the first recess.

13. The method of fabricating the semiconductor memory structure according to claim 12, wherein after forming the metal filling layer in the first recess further comprising following steps:
forming a third dielectric layer on a top portion of the metal filling layer, the third dielectric layer filled up the first recess.

14. The method of fabricating the semiconductor memory structure according to claim 12, wherein partially removing the first dielectric material layer and the second dielectric material layer comprises following steps:
using at least one of a dry etching process and a wet etching process, to partially removing the first dielectric material layer and the second dielectric material layer, with an etching rate of an etching selecting gas or an etching liquid related to the first dielectric material layer being greater than that of the second dielectric material layer.

15. The method of fabricating the semiconductor memory structure according to claim 12, wherein the second dielectric layer comprises a first sublayer and a second sublayer, while forming the second dielectric layer comprises following steps:
forming the first sublayer on the surface of a first dielectric layer; and
forming the second sublayer on a surface of the first sublayer, and the second sublayer filled up the first groove.

16. The method of fabricating the semiconductor memory structure according to claim 12, before forming the metal filling layer in the first recess further comprising following steps:
forming a fourth dielectric layer on an inner wall of the first recess.

17. The method of fabricating the semiconductor memory structure according to claim 12, wherein forming the metal filling layer in the first recess comprises:
forming a metal layer in the first recess, on the top portion of the second dielectric and on the upper surface of the substrate, the metal layer at least filled up the first recess; and
performing an etching back process on the metal layer, to remain the metal layer filled in the first recess to form the metal filling layer.

18. The method of fabricating the semiconductor memory structure according to claim 13, wherein forming the third dielectric layer on the top portion of the metal filling layer comprises:
forming a dielectric material layer on the top portion of the metal filling layer, the top portion of the second dielectric layer and the upper surface of the substrate, the dielectric material layer at least filled up the first recess; and
performing an etching back process on the dielectric material layer, to remain the dielectric material layer filled in the first recess to form the third dielectric layer.
